(19) United States
(12) Patent Application Publication
(10) Pub. No.: US 2013/0330828 A1
(43) Pub. Date: Dec. 12, 2013

(54) MINIATURIZED MAGNETIC FLOW CYTOMETRY

(71) Applicants: Oliver Hayden, Herzogenaurach (DE); Michael Johannes Helou, Regensburg (DE); Mathias Reisbeck, Obertraubling (DE); Sandro Francesco Tedde, Erlangen (DE)

(72) Inventors: Oliver Hayden, Herzogenaurach (DE); Michael Johannes Helou, Regensburg (DE); Mathias Reisbeck, Obertraubling (DE); Sandro Francesco Tedde, Erlangen (DE)

(73) Assignee: SIEMENS AKTIENGESELLSCHAFT, Munchen (DE)

(21) Appl. No.: 14/002,071

(22) PCT Filed: Feb. 28, 2012
(86) PCT No.: PCT/EP2012/052901

§ 371 Date: Aug. 28, 2013

(30) Foreign Application Priority Data
Feb. 28, 2011 (DE) 10 2011 004 805.7

(51) Int. Cl. G01N 15/14; H01L 43/12

(52) U.S. Cl. CPC G01N 15/1404; H01L 43/12
USPC 436/63; 422/73; 438/3

(57) ABSTRACT

A measuring device for magnetic flow cytometry has a microfluidic channel disposed along an enriching route such that a magnetically marked cell sample flowing through the microfluidic channel is aligned to magnetic guide strips, enriched by the magnetic field of a magnet at the floor of the channel, and guided past a sensor. The sensor and the magnetic guide strips are integrated on a semiconductor chip.

### CROSS REFERENCE TO RELATED APPLICATIONS

This application is the U.S. national stage of International Application No. PCT/EP2012/052901, filed Feb. 21, 2012 and claims the benefit thereof. The International Application claims the benefit of German Application No. 10 2011 004 805.7 filed on Feb. 28, 2011, both applications are incorporated by reference herein in their entirety.

### BACKGROUND

Described below are a device and a method for magnetic cell detection in a passing flow.

In the field of cell measurement and cell detection, magnetic detection methods are also known in addition to optical measurement methods such as stray light or fluorescence measurement, in which magnetic detection methods the cell type to be detected is marked by magnetic labels.

In particular, methods are known for magnetic-based measurements, in which magnetically marked cells are separated from a complex cell suspension, e.g. a blood sample, by magnetophoresis. To this end, this complex suspension firstly had to be prepared accordingly such that cells to be detected can be separated therefrom. In particular, magnetic marking takes place by virtue of the fact that cell-specific markers are introduced into the complex cell sample. Magnetophoresis was previously used for sorting magnetically marked cells or, in general, magnetic particles.

However, in the field of magnetoresistive sensors for cell detection, it is also possible for magnetically marked cells in a complex suspension to be counted dynamically in the passing flow. To this end, it is important that the cells flow individually over the sensor in succession and that the magnetically marked cells are guided over the magnetoresistive sensor in a sufficient proximity thereof.

Hence, in a magnetic flow cytometer, marked cells are transported over a magnetic sensor near the surface in a channel. The vicinity of a magnetically marked cell to the sensor is decisive since the magnetic stray field of the magnetic markers, on the basis of which the marked cell is ultimately detected by the detector, falls with the third power of distance.

In order to ensure that a marked cell passes the sensor in the direct vicinity thereof, it is, in principle, feasible to design the diameter of the channel through which the cell sample flows to be kept as small as possible. That is to say, in the extreme case, the channel diameter is just so big that individual cells are able to pass therethrough. The problem with this, of course, is that the presence of contaminants or interfering particles very quickly leads to the channel being blocked.

By contrast, if the channel has a larger design, this also increases the probability of some of the marked cells passing the sensor outside of the range thereof and therefore not being detected. This can be countered by virtue of the magnetically marked cells being enriched at the sensor: it was found that an enriching route, which is as long as possible, through a microfluidic channel with a length of up to 1 cm has a positive effect of virtually 100% of the magnetically marked cells from the complex suspension being enriched at the end of the enriching route on the channel floor in such a way that detection by a magnetic sensor is possible. However, such a long enriching route on a semiconductor substrate, on which the configured magnetoresistive component should be arranged, leads to a high aspect ratio of the substrate, which, in addition to high costs for the overall area of the semiconductor substrate, in particular for silicon dies, also leads to problems during processing in the production process. The higher the speed of the flow and the higher the cell concentration in the sample is, the longer the alignment route has to be selected in order to ensure sufficient enriching of the magnetically marked cells at the time of passing over the sensor.

### SUMMARY

Described below is a device for magnetic cell detection, which, with the same precision of enrichment and measurement, enables a reduction in the size of the semiconductor substrate, more particularly a silicon chip, and thereby also enables a simplification in the packaging of the measurement circuit on a printed circuit board.

The device for magnetic flow cytometry includes a magnetoresistive sensor, by which magnetically marked cells can be detected. Moreover, the device has a flow chamber, more particularly a microfluidic channel, which is configured for a cell suspension to flow therethrough. In particular, the microfluidic channel has an inlet to this end, through which the cell sample can be injected into the detection device. Moreover, it is possible for the interior surface of the microfluidic channel, e.g. in terms of its surface properties, to be adapted to a cell sample, in particular the viscosity thereof. The device moreover contains an enriching route, wherein the enriching route has a meandering design. Here, the enriching route expediently extends along the microfluidic channel. If the magnetically marked cell sample were to be guided onto or over a magnetic sensor directly after injection, it would naturally not be possible to detect all marked cells, since the magnetically marked cells are still unordered in the cell sample and distributed randomly in the full sample volume at the time of the injection of the cell sample into the device. Therefore the enriching route more particularly extends in an external magnetic field, which is generated by e.g. a permanent magnet. In this magnetic field for example, the magnetically marked cells in the cell suspension experience a magnetic force, by which they are moved e.g. in the direction of the channel floor of the microfluidic

channel. Hence the magnetically marked cells can be enriched on the channel floor and then be guided sufficiently closely over the magnetoresistive sensor. Only as a result of this is a reliable, substantially 100-percent detection of each individual magnetically marked cell ensured. The longer the enriching route is, the more assured it is that all magnetically marked cells are enriched on the channel floor by the time of passing over the sensor.

The advantage of the meandering enriching route lies in the reduced spatial requirements and the miniaturization of the whole measuring device, enabled thereby, and a possible integration of the whole measuring device on a semiconductor chip.

As a result of reducing the spatial requirements for the magnetophoretic enriching route, the device has the decisive advantage of making savings in the high costs of a semiconductor substrate, in particular an expensive silicon die. Moreover, as a result of a low aspect ratio of the die, simple processing is ensured. By way of example, the unpackaged semiconductor chip, an integrated electronic component, the semiconductor or sensor substrate is referred to as “die”.

Moreover, in addition to the semiconductor chip, the whole microfluidic volume is also reduced, leading to large cost savings and a simplification in the sensor production. The longer enriching route can advantageously be employed to increase the flow speed of the cell sample and therefore either increase the throughput and/or reduce the required measurement time for a sample.

The flow chamber, i.e., in particular, the microfluidic channel, has a diameter of e.g. approximately 1000 μm, corresponding to a multiple of a cell diameter. In principle, channel diameters between 30 μm and 30 000 μm can be realized.

In an advantageous embodiment, the enriching route of the device for magnetic flow cytometry has magnetic guide strips. In particular, these are arranged in such a way that they guide the cells toward the center of the channel floor. An advantage of this is that the magnetically marked cells, enriched on the channel floor, are aligned on e.g. a central magnetic guide line along the channel floor in such a way that individual cell detection is ensured when passing over the sensor. Moreover, the magnetic guide lines align the magnetically marked cells in such a way that the stray field thereof causes a signal which is as large as possible in the sensor.

It is particularly advantageous to have a ferromagnetic embodiment of the magnetic guide strips. In particular, the cells are magnetically marked by superparamagnetic markers.

The magnetic guide strips on the enriching route serve in particular to guide the cells more closely to the channel center. This is supported, particularly in the curvature regions of the meandering enriching route, by virtue of the fact that the magnetic guide strips are attached in such a way that they point to the channel center. Guiding toward the channel center is undertaken because the magnetoresistive sensor or e.g. a sensor array is arranged centrally in the channel at the end of the enriching and alignment route. Covering the whole channel width with individual sensors would make the measurement electronics more complicated. The magnetoresistive components can be arranged under the microfluidic channel, arranged in the channel wall of the microfluidic channel or else be arranged within the channel.

The device includes, in particular, a substrate, for example a semiconductor substrate, on which the magnetoresistive sensor and the microfluidic channel and also the enriching route are arranged. Here, the magnetoresistive sensor is more particularly integrated as “integrated circuit” on the semiconductor substrate. The microfluidic channel in turn extends more particularly along the enriching route on the substrate. By way of example, the magnetic guide strips of the enriching route can also be integrated on the semiconductor chip. The integrated solution of the device on a semiconductor chip has the advantages of compactness and small size.

In an advantageous embodiment, the microfluidic channel is arranged along the enriching route in such a way that a magnetically marked cell sample flowing through the microfluidic channel is aligned at the magnetic guide strips. This arrangement precisely has the advantage that the cells experience an alignment of the stray fields in addition to the enrichment on the channel floor, which enables highly sensitive individual cell detection at the sensor.

In particular, the device has a magnet to this end, which magnet is arranged with the device in such a way that a magnetically marked cell sample flowing through the microfluidic channel is enriched by the magnetic field of the magnet on the channel floor. To this end, the magnetically marked cells are marked, in particular, in superparamagnetic fashion. That is to say, in particular, superparamagnetic particles are attached to the cells. As a result of the magnetic field of the magnet, more particularly of a permanent magnet, the magnetically marked cells within the cell suspension experience a force guiding them in the direction of the channel floor.

In a further advantageous embodiment, the microfluidic channel and the magnetoresistive sensor are arranged in such a way that a magnetically marked cell sample flowing through the microfluidic channel is guided over the sensor. Thus, in particular, the sensor is arranged above or below the microfluidic channel such that a cell suspension flowing through the microfluidic channel is guided over the sensor close to the surface in any case. This sensor is expediently arranged at the channel floor or at a channel wall in the direction in which the magnetic field of the enriching magnet guides the magnetically marked cells. Accordingly, the sensor sees particularly precisely that side of the microfluidic channel on which the magnetically marked cells are enriched.

In an advantageous embodiment, the enriching route has a length of at least 12 500 μm, in particular at least 15 000 μm. By way of example, an enriching route of 1 mm length can also be sufficient. The required minimum length of the enriching route can also be 20 000 μm or up to 1 cm. The factors influencing the required length of the enriching and alignment route will still be explained below.

It was found that this long route length is advantageous in that even highly concentrated cell samples can be enriched on the channel floor at the end of the enriching route and aligned by the magnetic guide lines of the enriching route in such a way that reliable individual cell detection is ensured at the time when passing over the magnetoresistive sensor.

For such a long enriching route, the substrate more particularly measures at most 18 000 μm, at the very least at most 20 000 μm, along its greatest extent. By way of example, the substrate only measures at most 10 mm along its greatest extent. Here, most semiconductor dies are rectangular cutout wafer pieces and the maximum extent of the substrate accordingly is the diagonal thereof. Thanks to the meandering enriching route, the latter only has small spatial requirements on the substrate. This is particularly advantageous since the use of semiconductor substrates, more particularly silicon dies, is connected with high costs. Accordingly, the meandering enriching route ensures that a sufficiently long enriching route is realized in the case of a small semiconductor chip surface, by which it is also possible to enrich and align even highly concentrated cell samples in such a way that the magnetically marked cells in these cell samples can be detected individually by the magnetoresistive sensor. At the same time, the meandering shape of the enriching route reduces the aspect ratio of the substrate, meaning that the substrate becomes more compact and therefore simpler to process.

The magnetoresistive sensor of the device is, in particular, a GMR sensor (GMR=giant magnetoresistance). By way of example, the magnetoresistive sensor of the device is a TMR sensor (TMR=tunnel magnetoresistance) or the magnetoresistive sensor of the device is an AMR sensor (AMR=anisotropic magnetoresistance).

In alternative embodiments, use can also be made of optical sensors, such as fluorescence or stray light sensors, or these can be combined with magnetic sensors.

In the method for producing an above-described device, a magnetoresistive sensor is initially produced on a substrate, the magnetic guide strips are applied on the substrate and the microfluidic channel is attached to the substrate. In an advantageous embodiment of the production method, the sensor is integrated on the semiconductor substrate. To this end, known process methods from micro-system technology can be employed.

In an advantageous embodiment of the production method, the magnetic guide strips of the enriching route are deposited directly onto the substrate, for example by thermal evaporation or sputtering. The magnetic guide strips are, in particular, manufactured from a ferromagnetic material, e.g. from nickel. To this end, ferromagnetic alloys can also be employed.

In a measuring method for magnetic cell detection, a magnetically marked cell sample is injected into an above-described device with meandering enriching route, guided in a microfluidic channel within the device, enriched by a magnet on the channel floor in such a way that the magnetically marked cells are guided over the magnetoresistive sensor and detected there.

The enrichment by an external field, e.g. the field of a permanent magnet, and the magnetophoretic alignment by the ferromagnetic guide tracks may take place in situ during the measuring process. Therefore a sufficiently long alignment route is needed for the magnetically marked cells so as to ensure a desired retrieving rate of the marked cells of substantially 100%. Factors influencing the required length of the enriching and alignment route with the ferromagnetic tracks are:
1. the speed at which the cell sample is pumped through the microfluidic channel,
2. the magnetic field strength of the applied enriching magnetic field,
3. the concentration of the superparamagnetically marked cells in the suspension, as well as
4. the magnetic properties of the employed markers,
5. the composition and rheological properties of the cell suspension, i.e. e.g. the flow properties thereof, and
6. the type of the marked cells and the isotope number thereof on the cell surface and hence the number of paramagnetic markers per cell, which determines the strength of the stray field to be detected.

The cell suspension is pumped through the microfluidic channel by a pressure gradient in particular. The pressure gradient can for example be produced by manual operation of a syringe or a syringe system. What this ensures is that a laminar flow without recirculation is set in the cell sample. Since the cells and the complex medium surrounding the cells have approximately the same density, there are only small centripetal forces, even in the curvature regions of the meandering fluidic channel, and the marked cells can remain on their tracks.

The device and the measuring method are therefore particularly advantageous for small volumes of highly concentrated samples (1000 cells per μL), e.g. CD4+ cells. In the blood of a healthy adult, the CD4+ T-cells make up approximately 25%-60% of the lymphocytes. A blood sample would accordingly have a concentration of approximately 300-1600 cells/μL. An increase or reduction in CD4+ T-cells can occur in several diseases. Although the degree of increase or reduction cannot serve to deduce a disease, it can be an indicator therefor or additionally confirm an existing diagnosis. Examples in which an increase of CD4+ cells occurs are rheumatic diseases or else various forms of leukemia. A reduction in CD4+ cells can be an indication of an immunodeficiency, such as e.g. an HIV infection (AIDS).

Thus, what is decisive in magnetic flow cytometry is that the magnetically marked cells are transported very closely past the magnetoresistive sensor. Since the cell sample flows through a flow chamber, e.g. a microfluidic channel, the cells have to be transported close to the inner surface of the flow chamber, where the magnetoresistive sensor is applied, in the flow chamber. In particular, the channel wall is applied with direct contact over the magnetic sensor. The magnetoresistive sensor is embedded in the channel wall in alternate embodiments. Superparamagnetic labels may serve as magnetic markers. GMR, TMR or AMR sensors can be used as magnetoresistive sensors. The vicinity of the magnetically marked cell to the sensor is so decisive because the magnetic stray field of the magnetic marking falls with the third power of the distance in the near-field region. In addition to enriching the magnetically marked cells on the sensor surface, an alignment of the magnetically marked cells has a positive effect on the detectability thereof. Here, the magnetically marked cells may be aligned in the flow direction in such a way that the magnetic field of the magnetic marking causes a signal which is as clear as possible in the sensor. During magnetic flow cytometry, a differentiation between false positives and positive signals, which is as exact as possible, is required. To this end, a threshold for the signal which is as high as possible must be able to be set for positive signals so that these can be distinguished from noise signals.

In contrast to the method of guiding the magnetically marked cells individually over a sensor by virtue of being constricted in such a way in a microfluidic channel by the diameter thereof that only individual cells are able to pass through, the method has the advantage of enabling a substantially 100% individual cell detection, directly from the unprepared complex suspension. Hence the great disadvantage of the as it were mechanical separation of the cells, namely that these lead to blockages of the fluidic system, has been overcome. Nor was it possible in such a measuring device to determine magnetically marked cells with different diameters precisely in an individual fashion. By way of example, the cells have a diameter in the range from approximately 3 to 30 μm. They may be guided through a much wider microfluidic channel, the diameter of which is greater by a factor of 10 to 1000. The sensor or a sensor array of individual sensors is arranged transverse to the flow direction in this case and has for example a width of 30 μm, corresponding to the cell diameter.

### BRIEF DESCRIPTION OF THE DRAWINGS

These and other aspects and advantages will become more apparent and more readily appreciated from the following description of the exemplary embodiments, taken in conjunction with the accompanying drawings of which:

FIG. 1 is a schematic diagram of a meandering enriching route,

FIG. 2 is a representation of magnetic guide lines in the first curvature of the enriching route,

FIG. 3 is a representation of an alternative magnetic line arrangement in the first curvature of the enriching route,

FIG. 4 is a graph providing a size comparison between straight and meandering enriching route,

FIG. 5 is a cross section through a measuring device.

### DETAILED DESCRIPTION OF THE PREFERRED EMBODIMENT

Reference will now be made in detail to the preferred embodiments, examples of which are illustrated in the accompanying drawings, wherein like reference numerals refer to like elements throughout.

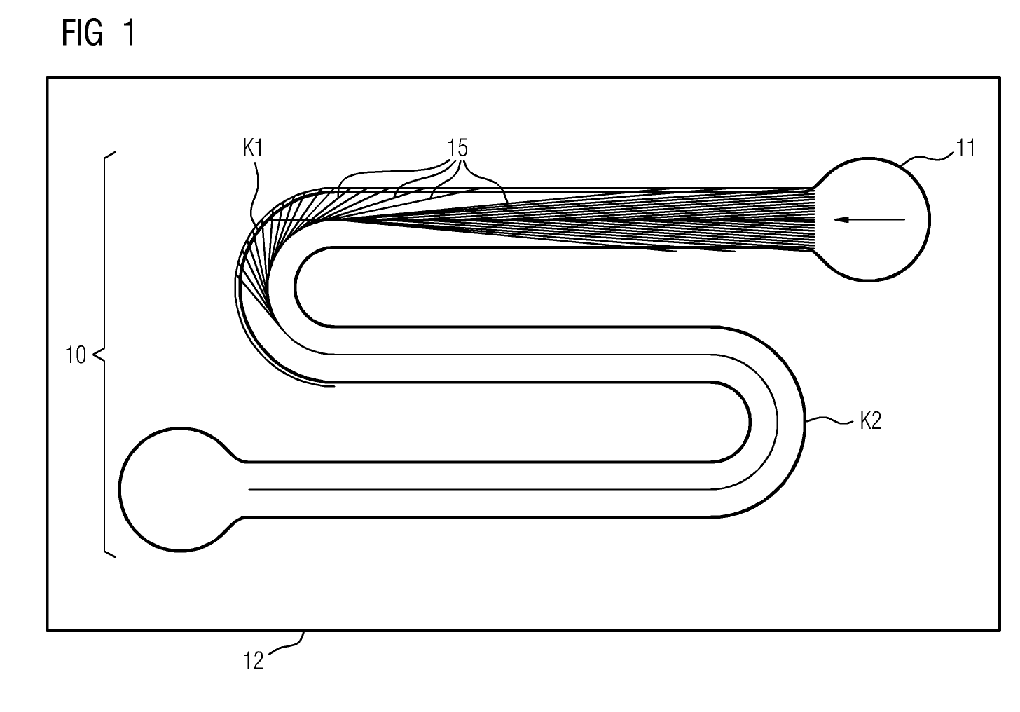

FIG. 1 shows a meandering enriching route 10 in accordance with one exemplary embodiment. The enriching route 10 has three straight partial routes, which are connected to one another by two curvatures K1, K2. The enriching route 10 is designed firstly to align but also to enrich magnetically marked cells 90 on the channel floor. That is to say, in the illustrated top view of FIG. 1, a microfluidic channel 50 is attached along the enriching route 10 in such a way that a cell sample, which is guided through this microfluidic channel 50, experiences the magnetic forces of a permanent magnet for enriching on the channel floor and also the magnetic interaction with the magnetic guide lines 15. The magnetic guide lines 15 shown in FIG. 1 extend along the enriching route 10, directly on the substrate 12, which more particularly is the surface of a semiconductor chip. Along the first straight partial route, the magnetic guide lines 15 converge at an acute angle to a center line of the enriching route 10 and therefore guide the magnetically marked cells 90 into the channel center. Along the first curvature K1, the magnetic guide lines 15 extend from the edge of the enriching route 10, i.e. also from the edge of the microfluidic channel 50, toward the center of the enriching route 10. This example shows a central magnetic guide line, which is always arranged along the channel center. Moreover, FIG. 1 shows, in the top view of the enriching route 10, an inlet 11 for a cell sample into the microfluidic channel.

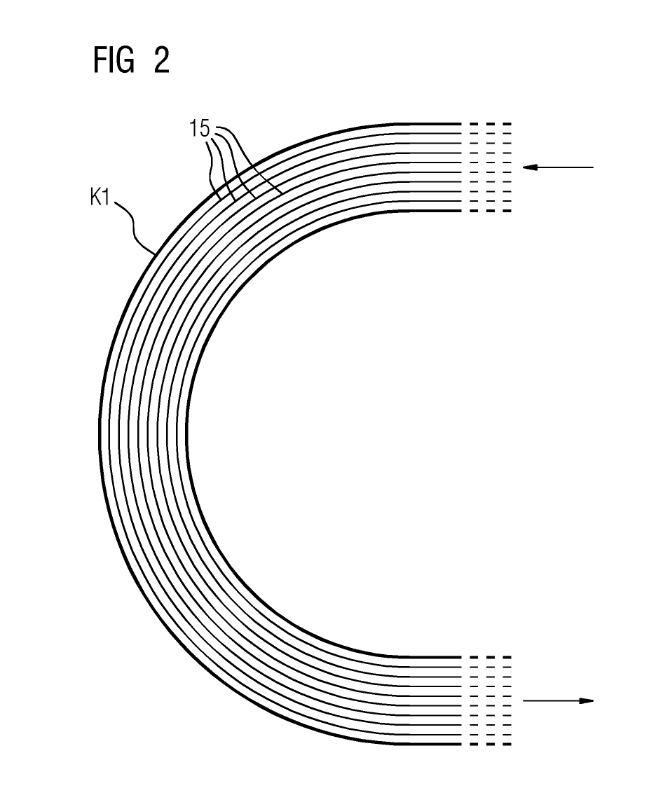

FIG. 2 shows a section of the enriching route 10 with the first curvature of the enriching route K1. FIG. 2 shows an alternative embodiment of the magnetic guide lines 15. Instead of converging in a fan shape to the center line, these can also be semicircular lines with different radii, which respectively describe a path with a fixed distance to the channel walls of the microfluidic channel 50. In this example, the magnetically marked cells 90 in the cell sample are guided through the curvature K1 on these paths. The arrows indicate the flow direction of the cell sample through the curvature K1 of the enriching route 10.

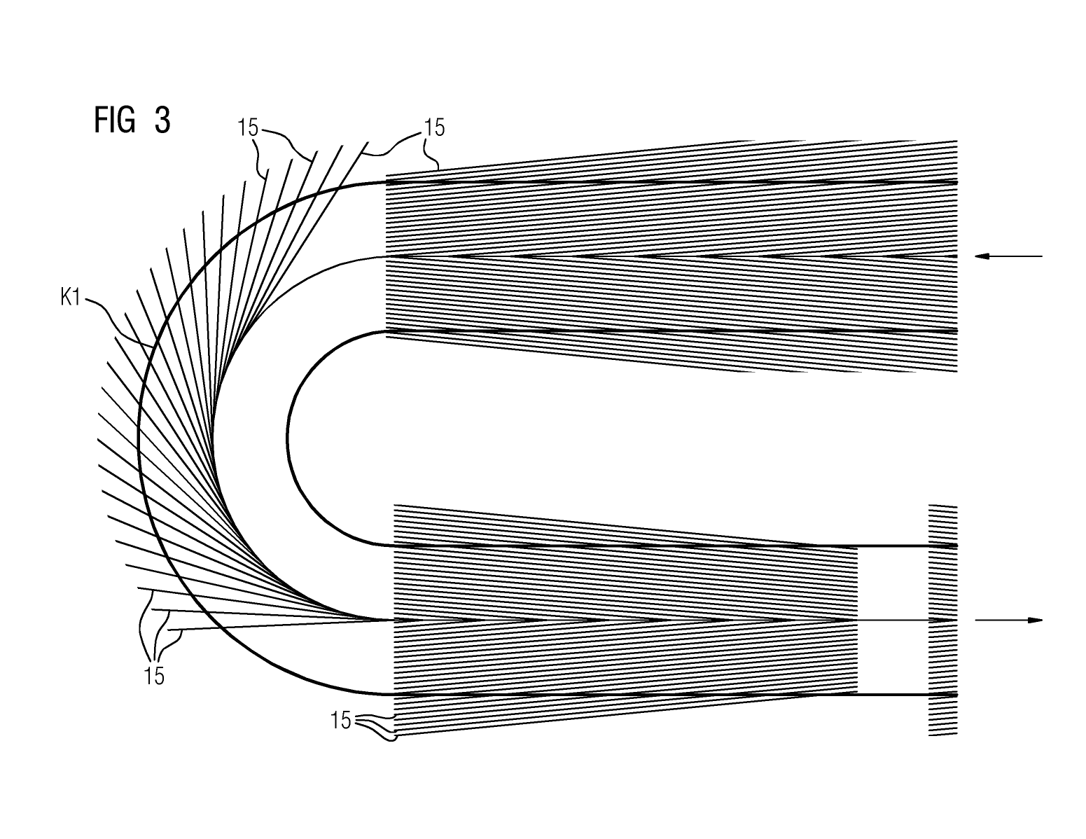

FIG. 3 shows a larger section of the enriching route 10, which shows the first curvature K1 and parts of the first and second straight partial route. The magnetic guide lines 15 once again show a fan-shaped picture in this embodiment. They lead from the channel wall toward the center line of the channel 50, both in the curvature K1 and on the straight partial routes. In particular, on the straight partial routes, they lead to the center line of the channel 50 at an acute angle. The cell sample 90 moved through the microfluidic channel 50 is accordingly guided to the center of the channel 50.

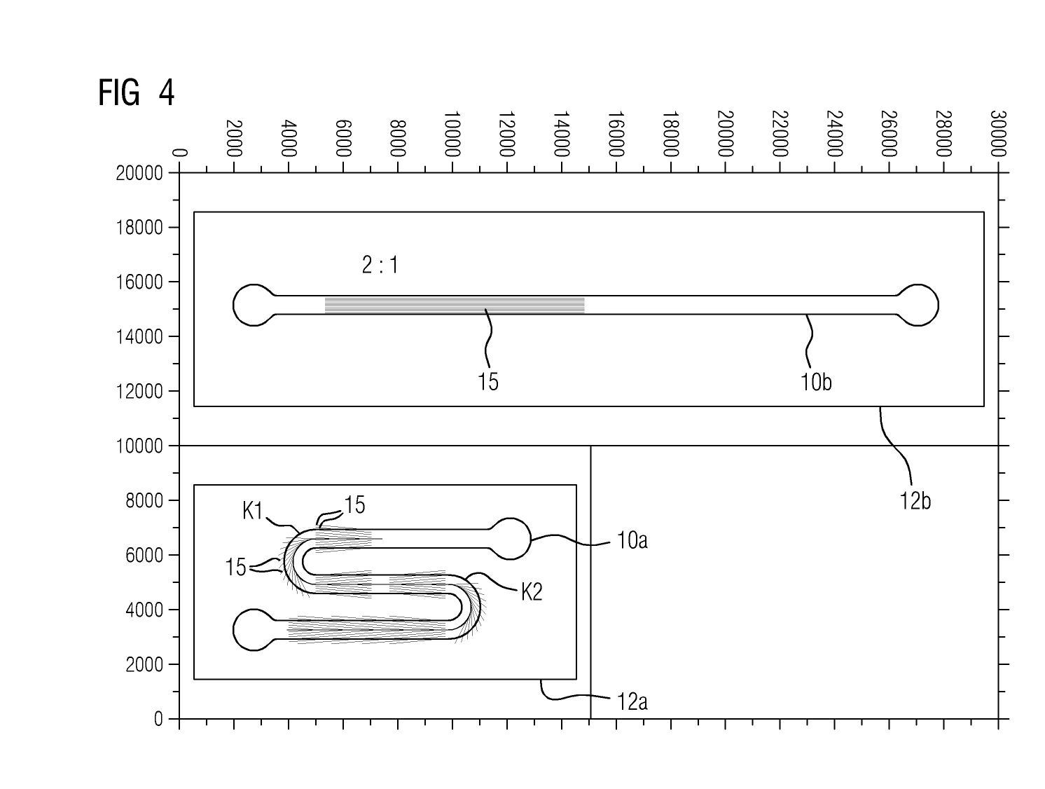

FIG. 4 shows a further top view of the enriching route 10a compared to a linear enriching route 10b. To this end, the length scales are specified in micrometers. The enriching route 10a has the same overall length as the linear enriching route 10b, but it only requires a semiconductor chip 12a half the size as substrate 12, on which the enriching route 10a in the form of magnetic guide lines 15 is arranged.

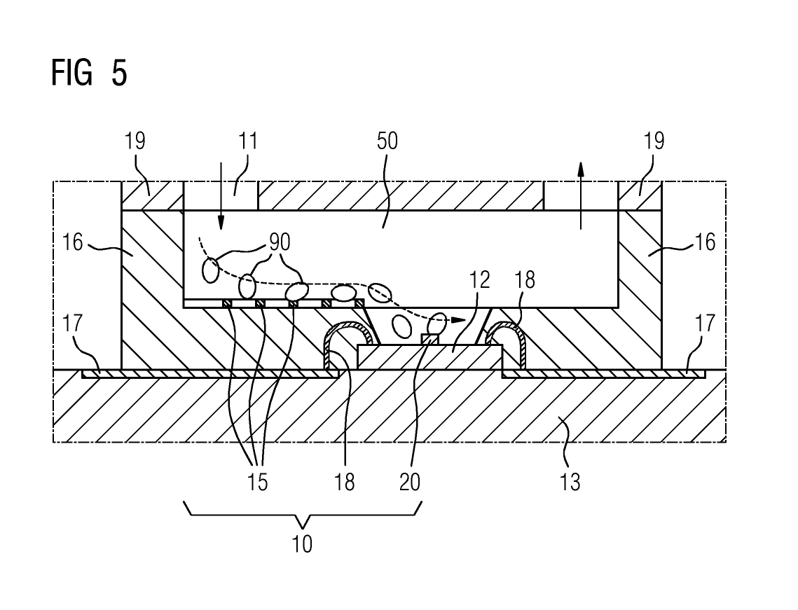

FIG. 5 shows a cross section through an embodiment of the measuring device, in which the enriching route 10 is not formed directly on the semiconductor chip 12, but rather on the packaging material 16. The cross section shows magnetic guide lines 15, by which the magnetically marked cells 90 are guided. In particular, a permanent magnet is arranged above or below the measuring device, by the magnetic field of which the cells 90 are enriched on the floor of the channel 50. FIG. 5 moreover shows a carrier 13, on which contacts 17 are deposited. The semiconductor chip 12 is applied to the carrier 13 and contacted to the carrier substrate 13 by wire bonding 18. Situated on the semiconductor chip 12 there is, in particular, a magnetoresistive sensor 20 and a small further section of an enriching route 600 with magnetic guide lines 15, which can compensate for an offset 601 to the enriching route 10 on the packaging material 16. By way of example, an injection molding method is used to form a flow chamber 50 using the packaging material 16. The arrows once again indicate the flow direction of the cell sample or denote the inlet 11 into the microfluidic channel 50.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 Fad 870, 69 USPQ2d 1865 (Fed. Cir. 2004).

1-14. (canceled)

15. A device for magnetic flow cytometry, comprising:
a magnetoresistive sensor;
a flow chamber configured for a cell suspension to flow therethrough; and
an enriching route, having a meandering design, for aligning and enriching a magnetically marked cell sample.

16. The device as claimed in claim 15, wherein the enriching route has magnetic guide strips.

17. The device as claimed in claim 16, wherein along curvatures of the enriching route the magnetic guide strips extend from an edge of the enriching route towards a center of the enriching route.

18. The device as claimed in claim 17, wherein the magnetic guide strips are ferromagnetic.

19. The device as claimed in claim 18,
further comprising a semiconductor substrate on which the magnetoresistive sensor, the flow chamber and the enriching route are arranged, and
wherein the flow chamber is a microfluidic channel.

20. The device as claimed in claim 19, wherein the microfluidic channel is arranged along the enriching route in such a way that the magnetically marked cell sample flowing through the microfluidic channel is aligned at the magnetic guide strips.

21. The device as claimed in claim 20, further comprising a magnet arranged adjacent a floor of the microfluidic channel so that the magnetically marked cell sample flowing through the microfluidic channel is enriched by the magnetic field of the magnet.

22. The device as claimed in claim 21, wherein the microfluidic channel and the magnetoresistive sensor are arranged so that the magnetically marked cell sample flowing through the microfluidic channel is guided over the magnetoresistive sensor.

23. The device as claimed in claim 22, wherein the enriching route is at least 12,500 μm long.

24. The device as claimed in claim 23, wherein the substrate has a longest dimension no greater than 18,000 μm.

25. The device as claimed in claim 24, wherein the magnetoresistive sensor is one of a giant magnetoresistance sensor, a tunnel magnetoresistance sensor and an anisotropic magnetoresistance sensor.

26. A method for producing a device having a magnetoresistive sensor, a flow chamber configured for a cell suspension to flow therethrough, and an enriching route, having a meandering design, for aligning and enriching a magnetically marked cell sample, said method comprising:
producing a magnetoresistive sensor on a substrate;
applying magnetic guide strips on the substrate; and
attaching the microfluidic channel to the substrate.

27. The method as claimed in claim 26,
wherein the substrate is a semiconductor substrate, and
wherein said producing of the magnetoresistive sensor integrates the magnetoresistive sensor onto the semiconductor substrate.

28. The method as claimed in claim 27, wherein said applying deposits the magnetic guide strips directly onto the semiconductor substrate by one of thermal evaporation and sputtering.

29. A method for magnetic cell detection, comprising:
injecting a magnetically marked cell sample into a device having a magnetoresistive sensor, a flow chamber configured for a cell suspension to flow therethrough, and an enriching route, having a meandering design, for aligning and enriching the magnetically marked cell sample
